(19) United States
(12) Patent Application Publication
(10) Pub. No.: US 2009/0243584 A1
(43) Pub. Date: Oct. 1, 2009

(54) Fabrication of microstructures integrated with nanopillars along with their applications as electrodes in sensors

(76) Inventors: Guigen Zhang, Bogart, GA (US); Venkataramani Anandan, New York, NY (US); Yeshwanth L. Rao, Burlington, MA (US)

Correspondence Address: STERNE, KESSLER, GOLDSTEIN & FOX P.L.L.C., 1100 NEW YORK AVENUE, N.W., WASHINGTON, DC, 20005, US

(21) Appl. No.: 12/232,152

(22) Filed: Sep. 11, 2008

Related U.S. Application Data
(60) Provisional application No. 61/039,338, filed on Mar. 25, 2008.

(51) Int. Cl. G01R 19/15; C25D 5/02; C25D 7/00; B32B 3/30

(52) U.S. Cl. 324/71.1; 205/135; 205/122; 205/112; 428/167

(57) ABSTRACT

This invention presents microstructures enhanced with nanopillars. The invention also provides a novel way for manufacturing nanopillar-enhanced microstructures, using conventional microfabrication techniques. In some embodiments, the invention also provides methods of use for the nanopillar-enhanced microstructures.

### CROSS REFERENCE TO RELATED APPLICATIONS

This application claims priority from U.S. provisional application 61/039,338, filed Mar. 25, 2008, which is incorporated herein by reference in its entirety.

### STATEMENT REGARDING FEDERALLY-SPONSORED RESEARCH

Part of the work performed during development of this invention utilized U.S. Government funds under ECS-0304340 awarded by National Science Foundation. Therefore, the U.S. Government has certain rights in this invention.

### BACKGROUND OF THE INVENTION

1. Field of the Invention

The present invention is directed to nanopillar-enhanced microstructures, their methods of use, and processes for developing nanopillar-enhanced electrodes.

2. Background Art

Biosensors are important devices for monitoring biological species in various processes of environmental, fermentation, food and medical concerns. The main challenges biosensors face include low sensitivity, poor specificity and proneness to fouling. The advent of nanotechnology presents promising solutions for alleviating these problems.

In a typical glucose biosensor, an enzyme such as glucose oxidase is immobilized onto the electrode surface [1,2]. The performance of such functionalized electrodes can be improved by either adjusting the spatial distribution of the enzyme or by modifying the morphology of the electrode surface. To achieve a high efficiency in immobilizing an enzyme onto the electrode surface, various techniques have been developed, such as the use of self-assembled monolayer [1-4], conducting polymers [5,6] and sol-gels [7]. Among these methods, the self-assembled monolayer (SAM) approach offers a better control for enzyme distribution at the molecular level, a high degree of reproducibility in enzyme immobilization and a short distance between the immobilized enzyme and the electrode surface [1,4]. The SAM approach, however, is limited by the amount of the enzyme that can be immobilized onto the electrode surface, which in turn will affect the sensing performance of the biosensor [8]. To increase the amount of immobilized enzyme various nanostructures such as nanopillars, nanoparticles and nanorods have been explored in order to increase the active surface area of the electrodes. For example, nanostructures like gold nanopillars [8], carbon nanopillars [5,9] and gold nanoparticles [10] have been incorporated into electrode surfaces and they exhibited better performance than conventional flat electrodes.

Recently Wang et al. [11] used nanostructured platinum electrodes functionalized with glucose oxidase for glucose detection. These electrodes showed a significant (two orders of magnitude) increase in glucose detection sensitivity as compared with a flat electrode, but the response of these electrodes to K₄Fe(CN)₆ was just 2.3 times that of the flat electrode. They attributed such sensitivity enhancements for glucose detection to the increased enzyme loading and improved retention of hydrogen peroxide near the electrode surface without examining systematically the role of reaction kinetics and mass transport. It is theorized that the electrical current response of these nanostructured electrodes is controlled by reaction kinetics, mass transport and the geometric topography of the nanostructures.

Surface acoustic wave (SAW) sensors are microelectromechanical (MEMS) systems in which the acoustic wave travels along the surface of a piezoelectric substrate. Interdigitated transducers (IDTs) are placed on the surface of a piezoelectric substrate to generate and receive the acoustic waves. The area between the generator and receiver IDTs is very sensitive to surface perturbation like mass loading. In a SAW sensor, this area is generally coated with a chemically selective layer for adsorption of analyte species. SAW based sensors have been widely used for gaseous, chemical and biological species detection. With the advent of nanotechnology, efforts have been made to increase the sensitivity of SAW sensors by integrating nanostructures on the active surface of the sensors.¹⁶⁻¹⁹

### BRIEF SUMMARY OF THE INVENTION

The present invention provides nanopillar-enhanced structures, methods for fabricating the same, and methods for using nanopillar-enhanced structures.

In one aspect, the present invention provides nanopillar enhanced electrodes for glucose detection. The electrodes are defined by an active three-dimensional (3D) surface formed by arrays of nanopillars standing on a flat support base. In one embodiment, the outer surface of the nanopillars is further functionalizes with glucose oxidase through either self assembly monolayer (SAM) molecules or polypyrrole polymer.

In another aspect, the present invention provides a method for fabricating nanopillar-enhanced electrode. In some embodiments, the nanopillar electrodes are fabricated by first coating a silicon wafer with several thin layers of metallic film anodizing the top layer to form a nanoporous template, sputter-coating one side of the anodized template, followed by electrodeposition of gold nanopillars and removal of the template. The nanopillars developed by electrodeposition are mechanically strong enough to sustain the hydrodynamic interactions produced during the electrochemical processes. Stated otherwise, nanopillars fabricated by this technique are resistant to deformation by capillary forces generated between the vertically aligned nanostructures and liquid medium.

Some embodiments of the present invention provide a process for fabrication of integrated structures of micro- and nano-scale features on a surface. In one embodiments, the nanopillar-enhanced surface can be micropatterned using conventional microfabrication techniques to produce a desired micro-pattern.

Another aspect of the invention provides a micro flow-channel glucose sensor with microscale-interdigitated planar electrodes incorporated with nanopillars. In one embodiment, the nanopillar-enhanced sensor comprises a micro-flow-channel design with an interdigitated arrangement (a working electrode is placed next to a detector electrode in an alternating manner) of micro planar electrodes enhanced by nanopillars. The micro-flow-channel design provides a convective flow for mass transport, whereas the current response of the planar electrodes are further enhanced by the addition of nanopillars and interdigitated arrangement.

In another embodiment, the integrated micro/nano structures fabricated by the process of the present invention are used as integrated elements in surface acoustic wave (SAW) based biosensor. The active surface of a SAW sensor described by the present invention is integrated with standing nanopillars with adjustable diameter and spacing in a process that is microfabrication compatible. Nanopillars formed by the electrochemical anodization and deposition are capable of withstanding capillary forces generated by the nanostructure-liquid interactions, and are ideally suited for sensing applications in aqueous environments. With such a SAW sensor, a multi-fold increase in detection sensitivity is achieved.

Another aspect of the present invention provides methods of use the micro/nano-structures described herein. In one embodiment, the micro/nano-structures of the present invention can be used in biosensors. In one embodiment, said biosensors can be used for remote detection of biological warfare agents (i.e., anthrax). In another embodiment, the biosensors with the integrated micro/nano structures fabricated by the process of the present invention can be used for in-vitro and ex-vivo monitoring of bioanalytes.

### BRIEF DESCRIPTION OF THE DRAWINGS

FIG. 1a illustrates, schematically, a nanopillar-enhanced electrode.

FIG. 1b illustrates, schematically, a nanopillar-enhanced electrode functionalized with glucose-oxidase with the use of anchoring molecule such as SAM or polypyrrole.

FIG. 2 illustrates, schematically, processing steps for fabricating micro patterns with nanoscale features on a silicon wafer.

FIG. 3 illustrates Scanning Electron Microscopy images of two samples of the developed integrated micro/nano structures on a glass substrate.

FIG. 4 illustrates, schematically, a micro flow-channel glucose sensor with microscale-interdigitated nanopillar-enhanced planar electrodes.

FIG. 5a illustrate, schematically, a conventional design for the microflow channel biosensor.

FIG. 5b illustrate, schematically, a microinterdigitated design for the microflow channel biosensor.

FIG. 6 illustrates, schematically, a two port SAW delay line sensor with a thin film of gold as an active layer enhanced by 12 nanostructures.

FIG. 7 is scanning electron microscopy (SEM) images of SAM Nano A, B and C speciments, with inserts showing a side-view of the speciments.

FIG. 8 is cyclic voltammograms obtained for three bare NAE's and a flat electrode.

FIG. 9a illustrates amperometric current responses obtained for the bare NAEs and flat electrode when incremental drops of K₄Fe(CN)₆ were added to the solution.

FIG. 9b is calibration curves obtained based on a linear regression analysis for the relationship between the steady-state current and K₄Fe(CN)₆ concentration.

FIG. 10a illustrates amperometric current responses obtained for the functionalized NAEs and flat electrode when incremental drops of glucose were added to the solution.

FIG. 10b is calibration curves obtained based on a linear regression analysis for the relationship between the steady-state current and glucose concentration (from 2.5 mM to 15 mM).

FIG. 11 illustrates variation of the steady-state current with glucose concentration (from 2.5 mM to 30 mM) for various functionalized electrodes along with the nonlinear-fitted curves based on the Michaelis-Menten equation.

FIG. 12 illustrates, schematically, a 2D model of a circular electrochemical cell containing a functionalized nanopillar electrode. The inner center circle is for generating the swirling vortex force to stir the solution and the small of center circle is for creating a drop of uniform concentration of glucose prior to the kinetics analysis. A magnified view of the nanopillar electrode is shown at the upper right corner.

FIG. 13a illustrates simulated currents responses for a functionalized NAEs electrode and a flat electrode at a reaction constant of 5×10⁻⁵ m/s and 5×10⁻⁷ m/s.

FIG. 13b is a contour plot for glucose concentration near the electrode at a reaction constant of 5×10⁻⁷ m/s.

FIG. 13c is a contour plot for K₄Fe(CN)₆ concentration near the electrode at a reaction rate constant of 5×10⁻⁴ m/s.

FIG. 14a illustrates a collection efficiency obtained at different electrode designs.

FIG. 14b illustrates a conversion efficiency obtained at different electrode designs.

FIG. 14c illustrates an amperometric current obtained for different electrode designs.

FIG. 15 illustrates, schematically, a fabrication procedure for a SAW sensor integrated with standing nanopillars.

### DETAILED DESCRIPTION OF THE INVENTION

In the following description, for purposes of explanation, specific numbers, materials and configurations are set forth in order to provide a thorough understanding of the invention. It will be apparent, however, to one having ordinary skill in the art that the invention may be practiced without these specific details. In some instances, well-known features may be omitted or simplified so as not to obscure the present invention.

The embodiment(s) described, and references in the specification to “one embodiment”, “an embodiment”, “an example embodiment”, etc., indicate that the embodiment(s) described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

As used herein, the term “biosensor” refers to a device for the detection of an analyte that combines a biological component with a physicochemical detector component. The term “analyte” refers to a naturally occuring and/or synthetic compounds, which are a marker for a condition (i.e., drug abuse), disease state (i.e., infection disease), disorder (i.e., neurological disorder), or a normal or pathologic process that occurs in a patient (i.e., drug metabolism). The term “analyte”, as used herein, can refer to any substance, including chemical and/or biological agents, that can be measured in an analytical procedure. Biosensors have potential use as a method of detection in many areas, including environmental, fermentation, food and medical areas. Biosensors could be used for in vivo or in vitro sensing in humans or animals. Currently, biosensors have a tendency to have low sensitivity, poor specificity and are prone to fouling. The biosensors of the present invention alleviate these problems.

### I. Nanopillar-Enhanced Electrodes

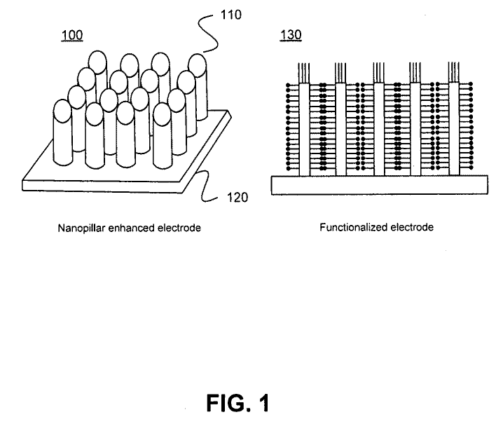

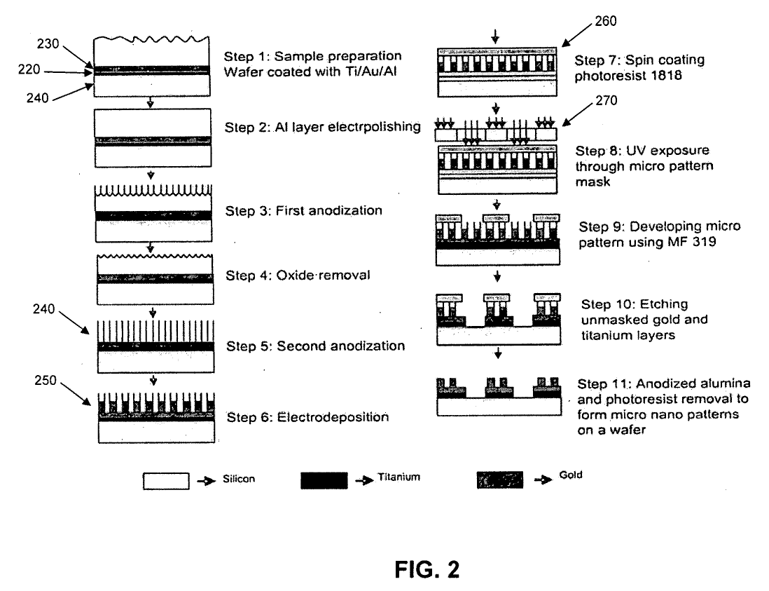

One aspect of the present invention, as illustrated in FIG. 1, provides a nanopillar enhanced electrode. As used herein, the term “electrode” refers to an electrical conductor used to make contact with a nonmetallic part of an electrical circuit, such as semiconductor, electrolyte, or a vacuum. The term “electrical circuit”, as used herein, is understood to mean a closed path formed by interconnection of a variety of electronic components available to the skilled artisan. A nanopillar of the present invention includes, but is not limited to, any nanoscale structure with a length-to-width ratio of 1 to 50, preferably 2 to 25, more preferably 3 to 15. A nanopillar of the present invention can be solid, hollow, and either porous or nonporous to liquids and gases. In one embodiment, the nanopillars of the present invention have a diameter in a range of 40-200 nm. In another embodiment, the nanopillars of the present invention have a diameter in a range of 120-170 nm. In yet another embodiment, the diameter of the nanopillars of the present invention range between 130 nm and 160 nm. In one embodiment, the nanopillars of the present invention have a diameter of 150 nm. In some embodiments of the present invention, the uniform height of nanopillars ranges between 0.1 μm and 10 μm. In one embodiment, the nanopillars of the present invention have the uniform height in the range of 0.75 μm-6.8 μm.

In one embodiment, the nanopillar-enhanced electrode comprises a 3D surface 100 formed by arrays of nanopillars 110 standing on a solid flat support base 120. Said 3D surface is used as the active surface for electrochemical reactions. The 3D surface of the present invention can be made of any comparable metal. A comparable metal of the present invention includes, but is not limited to, any metal, reduced or oxidized form of a metal, or any alloy that performs substantially the same function in substantially the same manner as the metal it is being compared to. In some embodiments, a comparable metal of the present invention comprises metals and metal oxides such as, but not limited to, gold, silver, platinum, aluminum, aluminum oxide, copper, palladium, or combinations thereof.

Base 120 may be any substantially flat or planar material. In certain embodiments, base 120 is a glass disk or a glass plate. In other embodiments, base 120 is a silicon chip or wafer. In other embodiments, base 120 can be a ceramic or concrete plate that has been manufactured to be substantially flat. Although reference is made above to disks, plates, or chips, it is understood that the nano-enhanced electrodes of the present invention can be formed onto any shaped base 120, so long as that base 120 is substantially flat or planar. The term “substantially flat or planar” as used herein means a surface that is uniformly flat or planar. It is understood that under today's conventional manufacturing techniques no surface is perfectly flat or planar. Some irregularities on the surface is acceptable.

The term “electrochemical reaction”, as used herein, refers to any chemical reaction which takes place in a solution at the interface of an electron conductor (a metal or a semiconductor) and an ionic conductor (the electrolyte), and that elicits chemical potential by the means of electron transfer between the electrode and the electrolyte or species in solution.

In another embodiment, a preferred feature of the invention is to functionalize the outer surface of at least one of the nanopillar-enhanced electrodes. In one embodiment, the electrodes are functionalized with macromolecules 130 on the surface. Examples of the macromolecules include, but are not limited to, any biomolecule capable of accelerating a reduction/oxidation chemical transformation utilizing any known redox co-factor. One example of a macromolecule suitable for use in the present invention is glucose oxidase. The electrodes can be functionalized with macromolecules in accordance with techniques known by those skilled in the art for depositing molecules to a surface. In one embodiment of the present invention, the surface is functionalized using a self-assembly monolayer (SAM) such as, for example, alkyl thiol. In an alternative embodiment, the surface is functionalized with macromolecules using polypyrolle polymers. Optionally, materials such as sol gel and/or carbon paste may be used to modify the surface (as a replacement for SAM or polypyrolle polymer, or in combination with either). The skilled artisan will be familiar with a variety of ways by which molecules can be added to a surface using SAM or polypyrolle polymers, any of which may be utilized within the scope of the embodiments of the invention. In one embodiment, the SAM or the polypyrolle polymer is placed on the surface of a nanopillar-enhanced electrode.

An increase in a detection sensitivity obtained with the electrodes of the present invention will be immediately appreciated by people skilled in the art. The performance of the electrodes described in the present invention can be evaluated by any of the variety of ways known to people skilled in the art by which electrochemical reactions are monitored. In some embodiments, the nanopillar-enhanced electrodes are characterized by an increased sensitivity in an analyte detection of at least 2-fold from that of a flat electrode. In one embodiment, the nanopillar-enhanced electrodes are characterized by an increased sensitivity in an analyte detection of at least 10-fold from that of a flat electrode. In yet another embodiment, the detection sensitivity of the nanopillar-enhanced is 100-fold higher than that of a flat electrode. As used herein, the term “flat electrode”, “planar electrode”, or “microplanar electrode” are used interchangeably to refer to an electrode that has not been enhanced by any nanostructures.

Previously, Delvaux et al. reported a sensitivity of a gold nanostructure-enhanced electrode for glucose detection to be 0.4 μA·mM⁻¹·cm⁻² [8]. In some embodiments, the sensitivity of the nanopillar-enhanced electrodes of the present invention in glucose detection is at least 2-fold higher than that of the gold nanostructure-enhanced electrode reported by Delvaux. In one embodiment, the sensitivity of the nanopillar-enhanced electrodes of the present invention in a glucose detection is at least 10-fold higher than the gold nanostructure-enhanced electrode reported by Delvaux. In yet another embodiment, the sensitivity of the nanopillar-enhanced electrodes of the present invention in glucose detection is at least 100-fold higher than that of the gold nanostructure-enhanced electrode reported by Delvaux.

### II. Methods for Fabricating Nanopillar-Enhanced Electrodes

Another aspect of the present invention describes a process for fabricating the nanopillar-enhanced electrodes, which comprises:
1) developing a nanoporous template by anodizing an aluminum sheet,
2) electrodepositing gold nanopillars, and
3) removing the template.

To date, a number of techniques have been described for fabricating various nanostructures. Among them, chemical vapor deposition technique (CVD), physical vapor deposition technique (PVD), and template-based electrodeposition technique are the most commonly used methods One of the major disadvantages of nanostructures prepared by CVD or PVD is their inability to sustain the capillary forces generated by the nanostructure-liquid interactions. When vertically aligned nanostructures are exposed to a liquid environment, capillary forces are generated between the vertically aligned nanostructures and the liquid medium. Often, the nanostructures are unable to sustain these forces, leading to their deformation or bunching. As a consequence of such deformations, the magnitude of increase in the surface area is drastically reduced, posing a serious problem for utilization of such nanostructures in aqueous-based biosensors. Nanopillars prepared by the process described herein possess sufficient mechanical stability to resist the capillary interaction forces.

As used herein, vertically standing nanopillars refers to nanopillars that are substantially vertical in orientation to the support substrate. In certain embodiments, the vertically standing nanopillars are essentially at a 90 degree angle to the support substrate.

It is understood that the above description is but one embodiment for fabricating the nanopillar-enhanced electrodes. For purposes of the present invention, the term “anodization” refers to a process whereby the valve metal in question (Al, Ti, Cr, Ta, etc.) is converted to its anodically generated oxide in aqueous acidic solution, typically a diprotic acid such as H₂SO₄, oxalic, phosphoric, etc. For the purposes of the present invention, the term “valve metal” refers to a metal that produces a stable oxide layer, such as titanium, tantalum, zirconium, niobium, chromium, etc. When aluminum is anodized in an appropriate acidic electrolyte under controlled conditions, it oxidizes to form a hydrated aluminum oxide (alumina) containing a two dimensional organized hexagonal array of cylindrical pores. The pore diameter and the interpore spacing depend primarily on the applied electrical potential and in a secondary fashion on electrolyte pH, temperature and aluminum microstructure (grain size).

In this embodiment, a nanoporous template 240 is prepared from any suitable metal known to those skilled in the art and guided by the teachings herein provided.

Examples of metal suitable for use in the present invention include any metal or any alloy that performs substantially the same function in substantially the same manner as the metal it is being compared to. In some embodiments, a comparable metal of the present invention comprises metals such as, but not limited to, aluminum, titanium, zinc, magnesium, niobium, or combinations thereof. In one embodiment, the metal used for formation of the nanoporous template is aluminum.

In one embodiment, the aluminum sheet may be created by first coating a flat surface 210 with several thin layers of metal. In one embodiment, the flat surface can be coated with at least two layers of metal. In one embodiment, the aluminum sheet is created by first coating the flat surface with a thin layer of metal (5-20 nm) 220, followed by another layer of metal (10-150 nm) 230. Examples of said surface suitable for the purposes of the present invention are those of a silicon wafer or a glass substrate. The metal layers can be made from the same or different metals, and can be any metal, reduced or oxidized form of a metal, or any alloy that performs substantially the same function in substantially the same manner as the metal it is being compared to. In some embodiments, a comparable metal of the present invention comprises metals such as, but not limited to, gold, silver, titanium, platinum, copper, palladium, or combinations thereof. In one embodiment, the metal used for formation of the first layer is titanium, and the second layer is gold.

An aluminum film with a thickness in a range of 900 nm-1.2 μm can be subsequently deposited onto the gold layer using any physical vapor deposition techniques known to the skilled artisans (i.e., an electron beam evaporation), followed by an electropolishing in a 9:1 ethanol to water solution. An anodization of the aluminum film can be performed under a variety of anodization conditions known to people skilled in the art. In one embodiment, a one-step anodization is carried out with the metalized wafer serving as the working electrode, and a piece of aluminum foil as the counter electrode. As used herein, the term “working electrode” refers to an electrode on which a reduction or oxidation reaction occurs. In an alternative embodiment, a two-step anodization is performed, wherein the formed oxide layer is removed before anodization is continued to the gold layer. The anodization conditions may be chosen, for example, to be constant potential at 40 V for 25 minutes in 0.3 M oxalic acid electrolyte at 3° C. In one embodiment of the present invention, the barrier layer at the bottom of the aluminum layer is removed. A person skilled in the art will appreciate a number of methods suitable for this purpose. In one embodiment, the barrier layer at the bottom of the aluminum layer is removed by immersing the wafer in 5 wt % phosphoric acid solution for 25 minutes, leaving a wafer with the anodized aluminum oxide (AAO) porous template 240 sitting on top of the gold film 230.

Nanopillars 250 can be formed through the open pores of the porous anodic alumina (PAA) template from any suitable material and by any of the suitable plating techniques known to the persons skilled in the art and guided by the teachings herein provided. Nanopillars can be made from any metal, reduced or oxidized form of a metal, or any alloy that performs substantially the same function in substantially the same manner as the metal it is being compared to. In some embodiments, a comparable metal of the present invention comprises metals such as, but not limited to, gold, silver, platinum, copper, palladium, or combinations thereof. In one embodiment, the metal used for formation of nanopillars is gold.

In some embodiments, gold nanopillars of a desired height are electrodeposited onto the PAA template. It is apparent to those skilled in the art and guided by the teachings herein provided that any suitable conditions can be used to electrodeposit gold onto PAA template. The conditions for electrodeposition may be chosen, as a way of an example, to be 5 mA/cm² electrical current applied to the PAA at 65° C. in a gold potassium cyanide bath. It will be appreciated by the skilled artisans that the height of the nanopillars can be controlled by varying the electrodeposition time. In some embodiment of the present invention, electrodeposition time is varied between 1 and 15 minutes.

The nanopillars developed by electrodeposition are mechanically strong enough to sustain the hydrodynamic interactions produced during the electrochemical processes. Stated otherwise, nanopillars fabricated by this technique are resistant to deformation by capillary forces generated between the vertically aligned nanostructures and liquid medium.

In some embodiments, PAA template can be removed following nanopillar formation. It is apparent to those skilled in the art and guided by the teachings herein that any suitable condition can be used for removal of the PAA template. By way of example, the PAA template may be removed by immersing the wafer in 1M NaOH solution for 25 minutes. In one embodiment, the PAA template can be removed completely. In another embodiment, said template may be partially removed to expose the tips of nanopillars. The term “partially”, as used herein, refers to removal of 10-80% of the template.

### III. Integrated Micro/Nanoscale Structures and Method for Producing Thereof

Microfabrication procedure has a strong impact in most of the areas of contemporary science and technology and the knowledge and experimental procedures for miniaturisation were transferred from electronics also to chemistry and biochemistry for creating sensors with better performances. The ability to generate patterns of biomolecules on different material surfaces is important for biosensor technology, tissue engineering, and fundamental studies in cell biology. There are several well established ways to pattern biomolecules onto substrates, such as photolithography, soft lithography, nano-pen lithography, and spotting techniques.

Photolithography, or patterning materials using photoresists and etching, is a technology known in the art, which has been advanced by progress in microelectronics where structures on the order of microns and submicrons are used. One of the major disadvantages of this technique, as it is known to date, is its inability to form structures with micro and nano (<100 nm) features on common wafers such as glass or silicon without causing severe deformation in the nanostructures due to its wet-process nature. Since the techniques of photolithography and microfabrication are widely accessible and commonly used at research labs and manufacturing facilities, any new process that is compatible with these techniques will bring widespread applications. Moreover, such a compatibility is also vital for a large-scale production of the said structures and electrodes, thus lowering the cost of production

One aspect of the present invention provides a process for producing integrated structures of micro- and nano-scale features on glass or silicon substrates. In some embodiments, such structures can be produced by micropatterning. In one embodiment, micropatterning can be achieved by coating the wafer enhanced with nanopillars fabricated by the process described above with a positive photoresist 260 (i.e., Photoresist 1818). The term “photoresist”, as used herein, refers to light-sensitive materials used to form a patterned coating on a surface (i.e., polyhydroxystyrene-based polymers). In one embodiment, photoresist may be applied to the wafer prior to the PAA template removal. In another embodiment, the PAA template will be removed prior to photoresist deposition. Photoresist may be deposited on the wafer using any of the variety of deposition techniques known to people skilled in the art. Examples of the suitable deposition techniques include, but are not limited to, spin-coating and electrodeposition. In some embodiments, photoresist will be spin-coated onto the wafer, followed by an exposure to a UV light through a micropattern mask 270. In some embodiments, the micropattern will be developed using a suitable developer solution (i.e., Microposit M 319). Following the development of the micropattern, the unmasked titanium and gold layers may be removed. A person skilled in the art will be familiar with a plethora of techniques available for metal removal. In some embodiments, the unmasked titanium and gold layers will be chemically etched, and photoresist stripped. Chemical etching may be done using any suitable material capable of dissolving metal (i.e., acid or base). In one embodiment, photoresist will be stripped from the wafer using any suitable photoresist strippers (i.e., hydroxylamine). Following micropatteming, PAA template may be removed by, for example, immersing the wafer in 1M NaOH solution for 25 minutes.

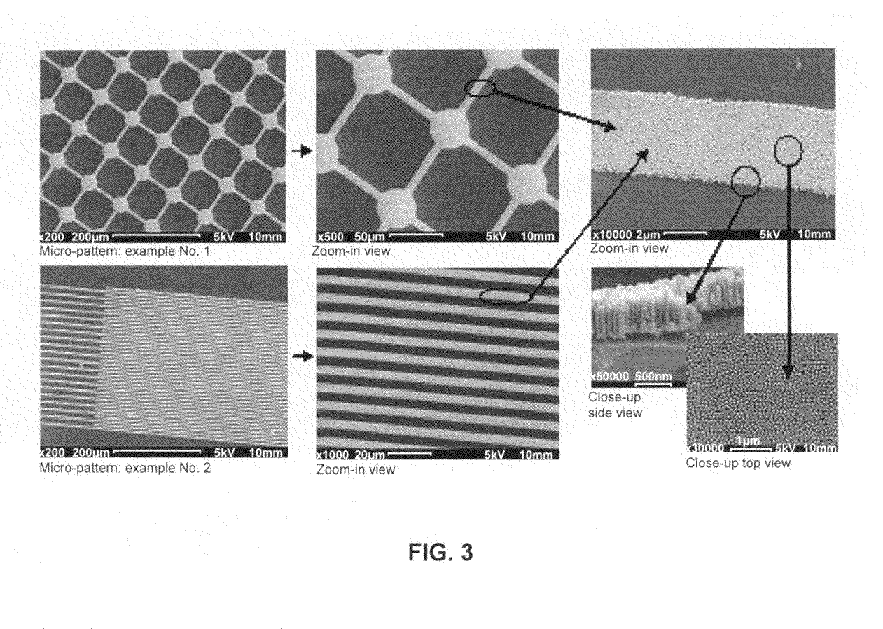

FIG. 3 illustrates two samples, by a way of example, of the developed integrated nanopillar-enhanced micropatterns on glass substrate. It will be appreciated by the skilled artisan that the number of designs for micropatterns fabricated by the process of the present invention is limitless.

### IV. Microflow Channel Biosensor

Another aspect of the present invention provides a microflow channel biosensor with planar electrodes incorporated with nanopillars. As used herein, the term “microflow-channel” refers to an apparatus designed for driving a microflow, or a fluid in small scales. It has been theorized that electrical current response of nanostructured electrodes depends on, among other factors, transport of analyte molecules to the active surface of the nanostructures, a process known as mass transport. Higher current response is achieved in instances wherein an analyte is able to diffuse into the deep spaces between the nanopillars to get oxidized. The detection sensitivity of the nanostructured devices described thus far has been limited by the diffusion rates of the analytes. A nanopillar-enhanced microflow channel biosensor described herein allows for bypassing a diffusion-limited sensor response by providing a convective transport of analyte molecules within said biosensor.

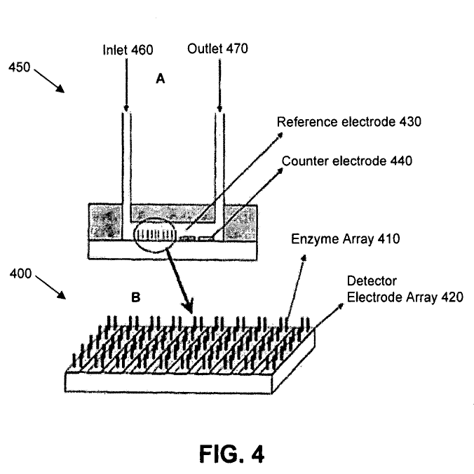

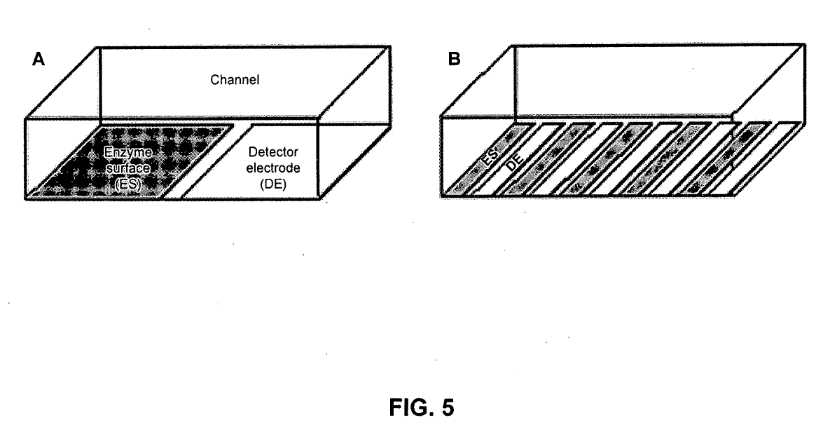

An example of a conventional arrangement of electrodes in the microflow channel biosensors is represented schematically on FIG. 5a. Present invention provides a new arrangement of electrodes, wherein planar electrodes are microscale-interdigitated, FIGS. 4 and 5b. As used herein, the terms “microscale-interdigitated” or “micro-interdigitated” are used interchangeably, and refer to an arrangement of electrodes, wherein a working electrode 410 is placed next to a detector electrode 420 in an alternating manner. The term “detector electrode”, as used herein, refers to an electrode capable of sensing an electrical current produced as a result of a redox reaction taking place at the working electrode. Such design will result in the enhanced performance of said biosensors, as judged by the improved collection and detection efficiency, due to the proximity of working and detecting electrodes.

In some embodiment, the working electrode can be functionalized with a macromolecule. Example of the macromolecules includes, but is not limited to, any biomolecule capable of accelerating a reduction/oxidation chemical transformation utilizing any known redox co-factor (i.e., FAD). In one embodiment, the macromolecule in the present invention is glucose oxidase. It will be apparent to the skilled artisan that glucose oxidase can be obtained by standard enzyme manufacturing techniques, such as microbial fermentation using traditional techniques or genetic recombination techniques. Alternatively, glucose oxidase can be purchased from industrial makers of enzymes, such as Amano Enzyme, Inc.

The electrodes can be functionalized with macromolecules in accordance with techniques known by those skilled in the art for depositing molecules to a surface. In one embodiment of the present invention, the surface is functionalized using a self-assembly monolayer (SAM) such as, for example, alkyl thiol. In an alternative embodiment, the surface is functionalized with macromolecules using polypyrolle polymers. Optionally, materials such as sol gel and/or carbon paste may be used to modify the surface (as a replacement for SAM or polypyrolle polymer, or in combination with either). The skilled artisan will be familiar with a variety of ways by which molecules can be added to a surface using SAM or polypyrolle polymers, any of which may be utilized within the scope of the embodiments of the invention. In one embodiment, the SAM or the polypyrolle polymer is placed on the surface of a nanopillar-enhanced electrode.

In some embodiments of the present invention, a microflow channel 450 consists of a micro-interdigitated array 400 of electrodes functionalized with a macromolecule 410 and detector electrodes 420.

Although microflow channel shown in FIG. 4 is equipped with an inlet 460 and an outlet 470, and additionally contains a reference electrode 430 and a counter electrode 440, it is apparent to those skilled in the art and guided by the teachings herein provided that in alternative embodiments, microflow channel of the present invention may be equipped with a number of other features suitable for its operation. The term “reference electrode”, as used herein, refers to an electrode which has a stable and well-known electrode potential. Examples of the reference electrode suitable for this invention include, but not limited to, a standard hydrogen electrode (SHE), a reversible hydrogen electrode (RHE), a saturated calome electrode (SCE), copper-copper (II) sulfate electrode, and palladium-hydrogen electrode. The term “counter electrode”, as used herein, refers to an auxiliary electrode used to make a connection to the electrolyte so that a current can be applied to the working electrode. A suitable material used for the counter electrode can be any inert material, such as copper, ruthinium, rhodium, palladium, silver, rhenium, osmium, iridium, platinum, gold, or graphite.

### V. SAW Sensors

Another aspect of the present invention provides MEMS devices integrated with micro/nano structures disclosed by the present invention. A person skilled in the will be familiar with a variety of conventional microfabrication techniques used for incorporating micro/nano structures into MEMS devices. Examples of the suitable microfabrication techniques include, but are not limited to, laser technology, microlithography, micromechatronics, micromachining and microfinishing (nanofinishing).

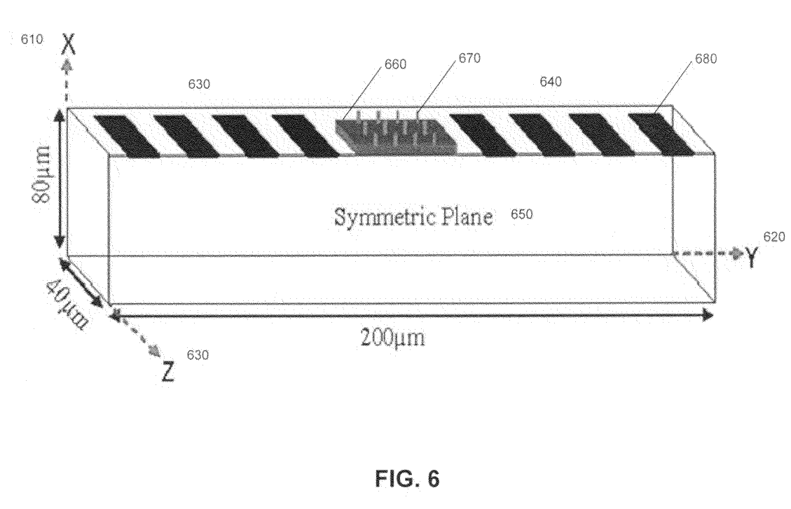

In some embodiments, micro/nano structures of the present invention will be incorporated into a surface acoustic wave (SAW)-based biosensor. Although FIG. 6 describe a two-port delay line SAW biosensor equipped with the nanopillar-enhanced electrodes, it is apparent to those skilled in the art and guided by the teachings herein provided that in alternative embodiments, other MEMS devices may be integrated with micro/nano structures disclosed by the present invention.

It will be appreciated by people skilled in the art that the following description is but one embodiment of a surface acoustic wave-based biosensor integrated with nanopillar-enhanced electrodes.

In one embodiment, depicted in FIG. 6, a two-port delay SAW sensor is constructed, consisting of generator 630 and receiver 640 interdigitated transducers (IDT), a piezoelectric material 650, and a chemically active layer 660. A person skilled in the art will realize a variety of dimensions, features, and configurations possible for the elements of the SAW-based biosensor described herein. The dimensions of the SAW device along the X 610, Y 620, and Z 630 axes can be 60-100 μm, 180-220 μm, and 30-50 μm, respectively. In one embodiment, the dimensions of the SAW device along the X 610, Y 620, and Z 630 axes are 80 μm, 200 μm, and 40 μm, respectively. As a way of an example, the generator and receiver IDT's can have several pairs of fingers, the width and spacing of which can be the same or different, and can range between 1-20 μm, preferably 5-15 μm, most preferably 7-13 μm. In one embodiment, the generator 630 and receiver 640 IDT's have two pairs of fingers with a width and spacing of 10 μm. The distance between generator and receiver IDT's can be varied by the skilled artisan to achieve a desired result in wave propagation and detection. In one embodiment, the sets of the IDTs can be place 10-70 μm apart. In another embodiment, the sets of the IDTs can be place 25-55 μm. In yet another embodiment, the distance between the IDTs will be 35-45. In one embodiment, the sets of IDTs are placed 40 μm apart.

People skilled in the art should know the requirement for a piezoelectric substrate in SAW sensors. The term “piezoelectric”, as used herein, refers to any material capable of generating an electric potential in response to an applied mechanical stress. Examples of the piezoelectric substrates suitable for use in the present invention include, but are not limited to, lithium niobate, potasium niobate, lithium tantalate, sodium tungstate, polyvinylidene fluoride, quartz, cane sugar, topas, Rochelle salt, berlinite, and the like, and the combinations thereof. In one embodiment of the present invention, lithium niobate is used as the piezoelectric substrate 650.

In one embodiment, the chemically active layer will be applied on the propagation path of an acoustic wave. As used herein, the term “active layer” refers to any material capable of adsorbing an analyte. Examples of a suitable material that can be used as an active layer in the SAW biosensors of the present invention include, but are not limited to, gold, and piezoelectric materials. It will be easily recognized by the skilled artisan that the dimensions of the active layer will depend on the dimensions of the biosensor, and the distance between the IDTs. In the embodiment depicted in FIG. 6, a nanopillar 670—enhanced gold film 660 with the dimensions 20 μm×20 μm×1 μm represents the chemically active layer. The shape of the nanopillars, as seen from the top, can vary, and can include round, square, triangular, rectangular, oval, and the like. The width of the nanopillars of the present invention can vary between 50 and 150 nm, preferably between 70 and 130 nm, more preferably between 90 and 110 nm. The height of the nanopillars can range between 0.1 μm and 10 μm. In some embodiment, the nanopillars have the height in the range of 0.75 μm-6.8 μm. In one embodiment represented in FIG. 6, gold square nanopillars have a width of 100 nm and height of 1 μm.

### VI. Methods of Use

Another aspect of the present invention provides methods of using the micro/nano-structures described herein. The vast number of potential applications of the micro/nano-structures described herein will be immediately apparent to persons skilled in the art. Below are but a few embodiments describing a potential utility of such structures.

In some embodiments, the micro/nano-patterned structures fabricated by the process of the present invention can be used in biosensors. One embodiment provides a method for use of the biosensors integrated with the nanopillar-enhanced electrodes fabricated by the process of the present invention for monitoring a target analyte level, comprising:

1) bringing said biosensor in contact with a sample;

2) detecting generation of free electrons;

3) determining whether the sample contains the target analyte by measuring an amperometric current, wherein the presence and magnitude of the current indicates the presence and the amount of the target analyte in the sample.

In some embodiments, biosensors integrated with nanostructures described herein can be used for a detection of a target analyte level in biological fluids. Examples of the target analytes include, but are not limited to, endogenously found molecules (i.e., glucose or lactose), exogenously consumed species (i.e., drugs or alcohol), toxic metabolites (mycotoxins), and pathogens (i.e., E. coli or Salmonella). Examples of the biological fluids include, but are not limited to blood, urine, serum, saliva, cerebra-spinal fluid, and semen. In other embodiments, biosensors integrated with nanostructures described herein are useful for environmental applications, such as detection of pesticides and river water contaminations. In some embodiments, biosensors integrated with nanostructures described herein can be used for a remote detection of biological warfare agents. Examples of the biological warfare agents include but not limited to: anthrax, ebola virus, ebola, Marburg virus, plague, cholera, tularemia, brucellosis, Q fever, machupo, Coccidioides mycosis, Glanders, Melioidosis, Shigella, Rocky Mountain spotted fever, typhus, Psittacosis, yellow fever, Japanese B encephalitis, Rift Valley fever, and smallpox. Naturally-occurring toxins that can be used as weapons include ricin (WA), SEB (UC), botulism toxin (XR), saxitoxin (TZ), and many mycotoxins.

In some embodiments, biosensors integrated with nanostructures described herein can be used for determining levels of toxic substances before and after bioremediation. In other embodiments, the biosensors integrated with nanostructures described herein find their application in drug discovery and evaluation of biological activity of new compounds. In yet another embodiment, the biosensors described herein are useful in determination of drug residues in food, such as antibiotics and growth promoters.

In some embodiment, the micro/nano-patterned structures of the present invention can be used for tissue engineering. For example, cell growth (i.e., neuronal) can be directed into intricate micro/nano-patterns of the present invention in a controlled way. In such embodiments, a micro/nano-pattern is prepared on a suitable substrate, i.e., glass plate or silicon wafer, cells are plated on the micropatterned substrate, and the cells are permitted to grow in a suitable nutrient medium. As the cells are permitted to grow, their growth along the micropattern along with exposure to nanoscale topographic environment may be stimulated by the signaling of the nanoelectrodes. In other words, the transmission of electrical signals along the micropatterned nanoelectrode stimulates cell growth along the path of the micropattern. Certain cell types can be stimulated by the use of appropriate hormones or cell active agents, such as cytokines or the like. In at least certain embodiments, the cells plated in the micropattern are stem cells.

### EXAMPLES

### Example 1

### Fabrication Process Used to Integrate Micro and Nanoscale Features Onto a Solid Substrate

| | |
|---|---|
| Step 1: | Sample preparation: A silicon wafer 210 is coated with a thin layer of titanium |
| | 220 (10 nm) followed by a layer of gold 230 (100 nm). Subsequently, a thick layer |
| | of aluminum (μm) is coated using an e-beam evaporator. |
| Step 2: | Electropolishing: The Al layer is then electropolished in a 9:1 ethanol to water |
| | solution. |
| Steps 3-5: | Anodization: A two-step anodization process is performed at a constant potential |
| | in oxalic acid. The Al layer is first anodized for a short duration followed by oxide |
| | layer removal using chromic acid solution. Then, second anodization is carried |
| | out all the way to the gold layer, leaving a wafer with the anodized alimunim |
| | oxide porous template 240. |
| Step 6: | Electrodeposition: Gold nanopillars 250 are formed by electrodeposition into the |
| | nanopores in a gold cyanide bath. |
| Steps 7-10: | Micro patterning: Photoresist 1818 (positive photoresist) 260 is spin coated on |
| | the sample and then exposed to UV light through a micro pattern mask 270. Then, |
| | the micro pattern is developed using MF 319 developer solution. Then, the |
| | unmasked gold and titanium layers are etched chemically following which the |
| | photoresist is chemically stripped. |
| Step 11: | Anodized alumina removal: The patterned sample is then placed in 2.0 M NaOH |
| | solution to dissolve away the anodized alumina, leading to a micro patterned |
| | structure with nanopillars. |

### Example 2

### Fabrication of Vertically Aligned Nanopillar Array Structures

Nanopillar array electrodes (NAEs) with three different pillar heights tested herein were fabricated using a template method [12]. It will be apparent to the skilled artisan that similar results will be obtained with the nanopillar-enhanced electrodes prepared by the process detailed in this invention.

In fabricating these electrodes, a layer of gold film about 150 nm thick was first sputter-coated onto one side of a porous anodic alumina (PAA) circular disc (d=25 mm; Whatman Inc, Maidstone, England) having an average pore diameter of 150 nm using a SPI sputter coater (Structure probe Inc, West Chester, Pa.). Then, a thicker gold layer was electrodeposited on top of the sputtered gold film to form a strong supporting base in an Orotemp24 gold plating solution (Technic Inc, Cranston, R.I.) with a current density of 5 mA/cm² for two minutes. This supporting base was masked with Miccrostop solution (Pyramid plastics Inc., Hope, Ark.) for insulation. After that, gold nanopillars were electrodeposited through the open pores of the PAA disc from the uncoated side under an electrical current density of 5 mA/cm² at 65° C. The deposition time was varied for achieving nanopillars of different heights. Specimens with three different nanopillar heights were prepared with the electrodeposition time controlled at 1, 7 and 15 minutes. After nanopillar deposition, the PAA disc was dissolved in 2.0 M NaOH resulting in a thin gold sheet with arrays of vertically standing gold nanopillars.

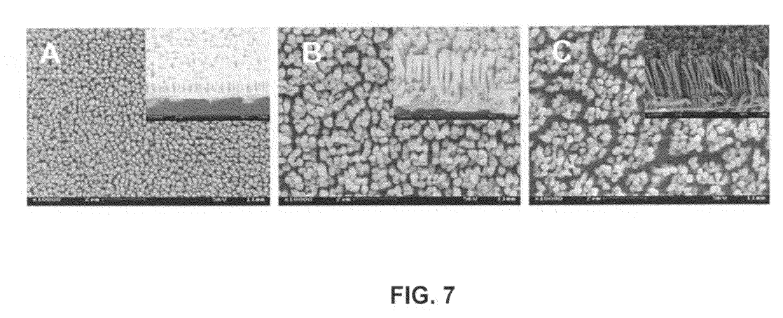

All resulting nanopillars had a diameter of about 150 nm, and varying heights of 1 μm, 2.5 μm and 6 μm for specimen A, B and C, respectively. The insets in FIG. 7 shows the side views of the specimens as seen on the scanning electron microscopy images. The fabricated specimens were cut into small square pieces (about 3.2×3.2 mm²) and they were grouped into specimens A, B and C by their nanopillar height. The electrodes with taller nanopillars (e.g., Nano B and Nano C) exhibit slight bunching deformations in nanopillars. This kind of deformation is caused by the capillary interaction (during the wetting of the electrodes) compounded by the reduced flexure rigidity of the taller nanopillars [12]. For connecting the electrodes, a copper tape were attached to the backside of an electrode with the exposed part of the copper tape insulated using Miccrostop. Prior to the electrochemical experiments, all electrodes (NAEs and flat) were cleaned by running cyclic voltammetry (CV) in 0.3 M H₂SO₄ between −500 mV and 1500 mV until a stable CV curve was obtained for each specimen, and then washed with deionized water.

### Example 3

### Evaluation of the Electrochemical Characteristics of the Nanopillar Array Structures

The electrochemical characteristics of the developed nanopillar array electrodes (NAE's) were evaluated in a three-electrode electrochemical system with nano-structured electrode used as a working electrode. Cyclic voltammetry (CV) was performed on the NAE's, using a flat gold electrode having the same geometrical area (about 16 mm²) as a control. The flat gold electrode was prepared by depositing a thin film (300 nm) of gold on titanium-coated glass plate using a thermal evaporator (built in-house). CV was performed in 0.5 M Na₂SO₄ supplemented with 4 mM K₄Fe(CN)₆ (JT Baker Inc., Phillipsburg, N.J., USA) at various scan rates (50 mV/s, 100 mV/s, 150 mV/s, and 200 mV/s). All runs were conducted in an unstirred solution using high purity deionized water.

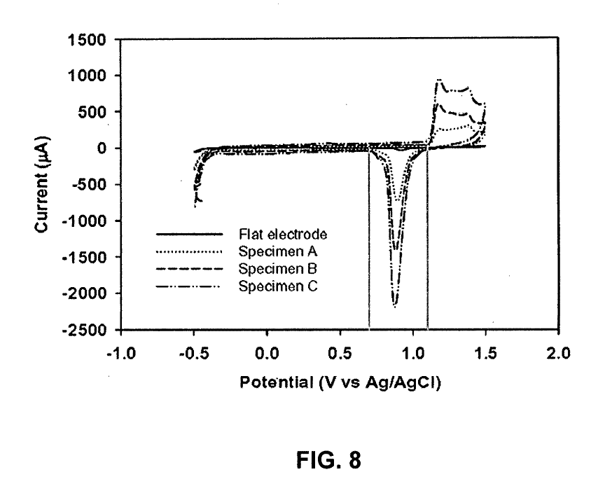

FIG. 8 shows the CVs for three NAE's and a flat electrode. In all these voltammograms, a reduction peak is seen in between 0.70 V and 1.1 V. As used herein, the term “roughness ratio” is defined as the area under the reduction peak (calculated by integrating the voltammogram from 0.70 V to 1.1 V) of an NAE electrode divided by that of the flat electrode, and is useful in quantifying the difference in the height of the nanopillars in these NAEs. The roughness ratio was found to be about 20, 38.8 and 63.4 for specimens A, B and C, respectively (see Table 1).

TABLE 1
The roughness ratio, detection sensitivity, Iₘₐₓ and
Kₘ obtained from experiments

| | | Sensitivity of | Sensitivity of | | |
|---|---|---|---|---|---|
| | | bare | functionalize | | |
| | | electrodes to | electrodes to | | |
| | Roughness | K₄Fe(CN)₆ | glucose (μA | Iₘₐₓ glucose | Kₘ glucose |
| Specimen | Ratio | (μA mM⁻¹ cm⁻²) | mM⁻¹ cm⁻²) | (μA) | (mM) |
| Flat | 1.0 | 19.30 | 0.27 | 1.34 | 24.8 |
| Nano A | 20.0 | 41.40 | 0.91 | 5.06 | 29.3 |
| Nano B | 38.8 | 41.05 | 1.80 | 10.1 | 32.6 |
| Nano C | 63.4 | 41.70 | 3.13 | 23.0 | 52.0 |

### Example 4

### Evaluation of the Sensitivity of the Nanopillar Array Structures: Flat Electrode Versus NAE

The sensitivity of the nano-structured electrode as compared to the flat electrode was asses by evaluating their amperometric current responses in 0.5 M Na₂SO₄ solution supplemented with either 6 different concentrations (4 mM, 8 mM, 12 mM, 16 mM, 20 mM, and 24 mM) of K₄Fe(CN)₆. The transient current was measured at a constant potential of 350 mV versus Ag/AgCl, and the change in the current response upon the change in K₄Fe(CN)₆ concentration for both the NEAs and flat electrode was determined. The solution was stirred constantly for the duration of the experiments using a magnetic stirrer.

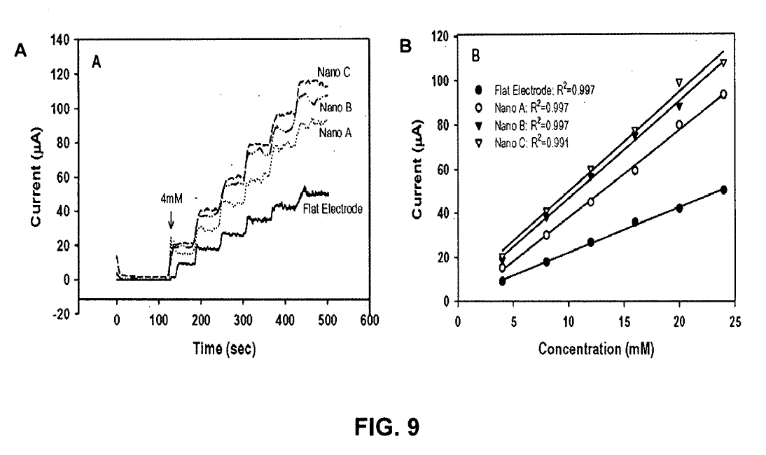

FIG. 9a shows the amperometric current response for the NAEs and flat electrodes at various K₄Fe(CN)₆ concentrations. In general, all the NAEs exhibited a higher current than the flat electrode at each K₄Fe(CN)₆ concentration. To further quantify the sensing performance of these electrodes, the relationship between the current response and K₄Fe(CN)₆ concentration was analyzed by a linear regression analysis. FIG. 9b shows the variation of the steady-state amperometric current with the concentration of K₄Fe(CN)₆ (4 mM, 8 mM, 12 mM, 16 mM, 20 mM, and 24 mM) along with the corresponding regression lines. By taking the slope of the regression lines and normalizing it with respect to the geometrical area of the electrodes (3.2 mm×3.2 mm), sensitivity values for the electrodes were obtained and these values are listed in Table 2. For all the electrodes, the NAEs showed sensitivity about two times higher than that of the flat electrode.

The sensitivity of the bare NAEs did not increase with the increase of the roughness ratio. This is explained by the fact that only the top part of the nanopillars is contributing to the increase of active electrode surface for electron transfer, and the electroactive species K₄Fe(CN)₆ may encounter certain difficulties in its transport to the small spaces between the bare nanopillars as the result of either a low diffusivity or a fast electron transfer rate constant. With a low diffusivity, it is difficult for K₄Fe(CN)₆ to diffuse deep into the small spaces between the nanopillars, while with a fast electron transfer rate constant, most of the species K₄Fe(CN)₆ get oxidized near the top ends of the nanopillars before it diffuses down the gaps.

### Example 5

### Evaluation of the Sensitivity of the Nanopillar Array Structures: Functionalized NAE's Versus Flat Electrodes

To functionalize the electrodes, their surfaces were first modified with a SAM layer by placing them in a 75% ethanol solution containing 10 mM 3-mercaptopropionic acid. Then the SAM modified electrodes were rinsed in 75% ethanol and immersed in a 0.1 M 2-(Nmorpholino)ethanesulfonic buffer solution (pH of 3.5) containing 2 mM 1-ethyl-3-(3-dimethylaminopropyl)carbodiimide hydrochloride and 5 mM N-hydroxysuccinimide for activation for two hours. After washing in phosphate buffer solution (PBS), the activated NAEs were placed in PBS solution at pH 7.4 containing 1 mg/ml of glucose oxidase for two hours under constant stirring. The reason for setting the immobilization time to two hours is that according to literature [13], enzyme loading reaches its maximum in about 2 hours and it saturates afterwards. From the electrochemical experiments, the amperometric current responses of both bare and functionalized NAEs along with flat controls were measured using a conventional three-electrode cell with an Ag/AgCl reference electrode and a platinum counter electrode with the Multistat 1480 (Solartron Analytical, Houston Tex., USA) electrochemical system.

For the functionalized NAEs, the amperometric current responses to each incremental addition of 50 μl of 1 M glucose to a 20 ml PBS solution (equivalent to a 2.5 mM increase in glucose concentration) containing 3 mM p-benzoquinone as a mediator were measured at a constant potential of 350 mV (vs. Ag/AgCl). In all experiments, the background current of all electrodes was allowed to stabilize before drops of target species were added. Prior to these experiments the electrolyte solution was de-aerated with nitrogen and during experiments the solution was blanketed with nitrogen and stirred constantly at 600 rpm.

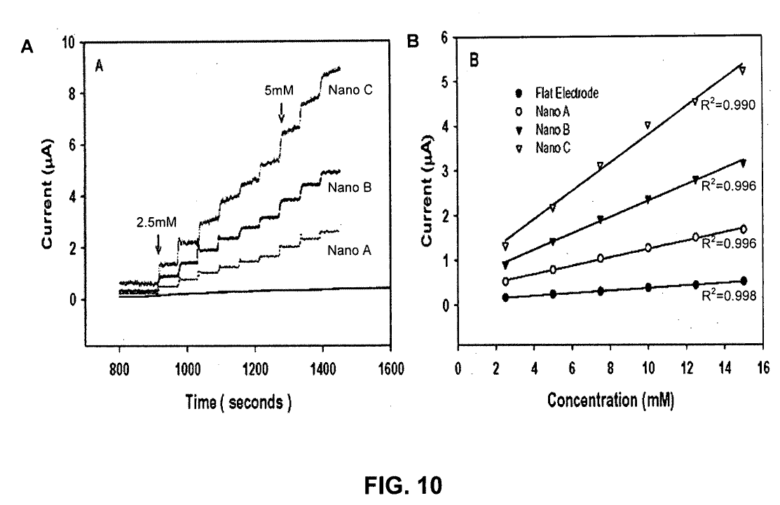

FIG. 10a shows the amperometric currents for the functionalized NAEs and flat electrode at various glucose concentrations. All the NAEs exhibited a higher current response than the flat electrode at each glucose concentration. In each incremental step, the current response of Nano C is still rising indicating that it has not reached its steady state. This phenomenon may be due to the increased response times for electrodes with taller nanopillars. However, for a quick comparison between these nano electrodes, a more conservative approach was taken to get the current readings for Nano C at the same time as for Nano B and Nano C.

FIG. 10b shows the variations of the steady-state amperometric current with glucose concentration (from 2.5 mM to 15 mM) along with the corresponding linear regression lines. By taking the slope of the regression lines and normalizing it with respect to the geometric area of the electrode in each case, the sensitivity measurement were obtained for the functionalized electrodes (NAEs and flat). From the obtained sensitivity values listed in Table 2, it was observed that unlike in the bare electrode cases, the sensitivity of NAEs increases as the roughness ratio increases. The highest sensitivity value (Nano C) is about 3.13 μA·mM⁻¹·cm⁻² (about 12 times higher than that for a flat electrode) which is significantly higher than the value reported for a gold nanopillar electrode (0.4 μA·mM⁻¹·cm⁻²) [8]. So for the functionalized NAEs, increasing the surface roughness of the NAEs does contribute to an increase in detection sensitivity.

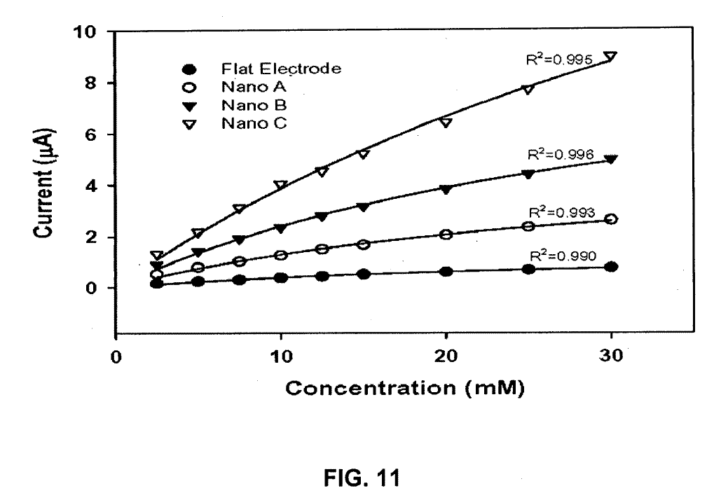

FIG. 11 shows the variations of the steady-state amperometric current with the glucose concentration over a wider concentration range (2.5 mM to 30 mM). As used herein, the term/symbol “Iₘₐₓ” refers to the maximum current attainable, the term/symbol “Kₘ” refers to the apparent Michaelis-Menten constant and describes the enzymatic activity of glucose. By performing nonlinear curve fitting to the data using standard Michaelis-Menten equation, values for Kₘ and Iₘₐₓ were obtained in each case as listed in Table 2. Both Iₘₐₓ and Kₘ values are higher for the NAEs than for the flat electrode and they increase as the roughness ratio increases. Furthermore, the Kₘ values for all the NAEs are larger than the reported intrinsic Kₘ value of 25 mM for dissolved glucose oxidase [16]. This indicates that the activity of the enzyme immobilized on these NAEs has actually been lowered as compared with the freely dissolved enzyme, which further suggests that the increase in sensitivity in the functionalized NAEs is due to factors other than enzyme activity.

In comparing the bare with the functionalized electrodes, it was observed that the highest nanostructure-induced sensitivity increase for the functionalized electrodes (12 times) is higher than that for the bare electrodes (2 times). This could be due to the difference in electrochemical species involved (i.e., glucose versus K₄Fe(CN)₆). These two electroactive species, however, have a similar diffusivity value (8×10⁻¹⁰ m²/s for K₄Fe(CN)₆ and 7.6×10⁻¹⁰m²/s for glucose) [14]. This fact suggests that the difference in the reaction rate constant at the bare and functionalized electrodes may play a more dominate role in affecting the current response. It is also possible that such an increase in the sensitivity of functionalized NAEs is the result of heightened retention of the mediator during glucose detection [11].

### Example 6

### Evaluation of the Effects of Reaction Kinetics and Mass Transport on the Current Response of Bare and Functionalized NAEs

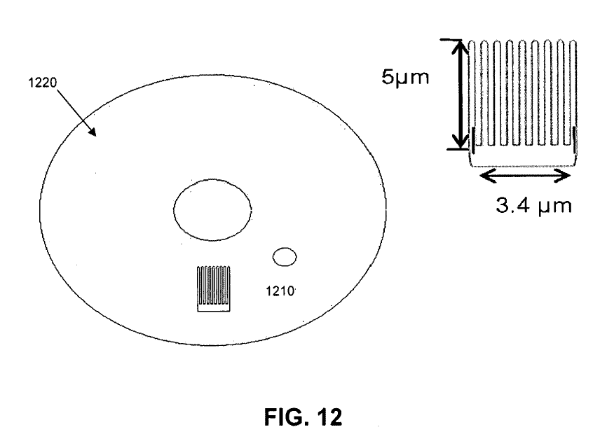

An electrochemical process was simulated using a finite element analysis method with commercial software COMSOL Multiphysics (COMSOL Multiphysics, Burlington, Mass.). To simplify the situation, two-dimensional situations were considered. As shown schematically in FIG. 12, a set of NAEs 1210 (with a width and a spacing of 200 nm for the pillars, and an overall dimension of 5 μm×4.3 μm for the electrode) was placed in a circular electrochemical cell 1220 containing a supporting electrolyte. In this simulation, a bare and a glucose oxidase-functionalized NAEs, as well as a flat electrode with the same planar area (as a control), were considered.

For the electrode reaction at the functionalized NAEs, it was assumed that glucose was consumed at a flux of J_{g} at the electrode surface to produce the mediator in its reduced form at a flux of J_{M}. Here J_{g} and J_{M} can be described by the following equations:

J_{glucose}=kc_{G} (5)

J_{M}=kc_{G}−k₀c_{M} exp(−αF(E−E_{std})/RT) (6)

where k represents the rate constant for Eq. 5, c_{G} the concentration of glucose, c_{M} the concentration of mediator, k₀ the standard rate constant, α the charge transfer coefficient, F the Faraday constant, E the electrode potential, and E_{std} the standard potential of the mediator. To simulate the actual event, the electrode was held at a constant overpotential of 350 mV. Under this condition, the reduced-form mediator was oxidized at the electrode surface to generate a current flux of J_{c}:

J_{C}=−2k₀c_{M} exp(−αF(E−E_{std})/RT) (7)

With these considerations, the amperometric current response of the electrodes in response to a drop of glucose was determined while the electrolyte solution was constantly stirred by a swirling vortex force applied at the center of the cell.

For the electrode reaction at the bare-electrode, it was considered the redox of K₄Fe(CN)₆ with the reduction flux of K₄Fe(CN)₆ governed by:

JF=−k0FcF1 exp(−αF(E−E_{std}′)/RT)+k0FcF2 exp(−αF(E−E_{std}′)/RT) (8)

where k_{0F} is the electron transfer rate for both ferrocyanide and ferricyanide (assumed to be the same), c_{F1} the concentration of ferrocyanide, c_{F2} the concentration of ferricyanide, E the electrode potential, and E_{std}′0 the standard potential of ferro- and ferri-cyanide.

Besides the reaction kinetics discussed above, the mass transport in these electrochemical processes was mainly governed by diffusion and convection for the mobile species such as glucose and K₄Fe(CN)₆. The electromigration was ignored because of the presence of the supporting electrolyte in a high concentration.

After these considerations, the diffusion/convection-controlled electrochemical reaction problems upon a step potential excitation (350 mV) at the electrode were solved using the combined Electrokinetic-Flow and Navier-Stokes applications in COMSOL Multiphysics. In the simulation process, two initial analyses were performed. First, a stationary nonlinear analysis in Navier-Stokes mode was performed for reaching a fully developed vortex flow inside the center inner circle (FIG. 12), and then a stationary nonlinear analysis in Electrokinetic-Flow mode was performed for producing a uniform initial concentration of glucose within the off-center inner circle (FIG. 12), much like dropping a small volume of glucose into the solution. After these initial steps, time dependent analyses were performed. For the kinetic constants, literature values [15] including the diffusivity of ferrocyanide and ferricyanide listed in Table 2 were used. The values for the diffusivity of glucose and the mediator, which are not readily available in the literature, were calculated using the following equation [15]:

TABLE 2
Material constants and kinetic parameters used in the simulation.

| Parameter | | Value |
|---|---|---|
| k₀ | Standard rate constant | 1.5 × 10⁻³ (m/s) |
| ε_{B} | Association factor | 2.6 |
| α | Charge transfer coefficient | 0.5 |
| T | Absolute temperature | 298 (K) |
| μ | Viscosity | 1.1 (cP) |
| V_{A} | Molar volume | 0.1176 (m³/mol) |
| rₚ | Pore radius | 200 × 10⁻⁹ (m) |
| L | Pore length | 5 × 10⁻⁶ (m) |
| k | Surface reaction rate | 5 × 10⁻⁴, 5 × 10⁻⁵, |
| | constant | 5 × 10⁻⁷ (m/s) |
| M_{B} | Molecular weight of water | 18 |
| R | Gas constant | 8.31 (J/K. mol) |
| F | Faraday constant | 9.648 × 10⁴ (C/mol) |
| D_{F} | Diffusivity of ferro- and | 8 × 10⁻¹⁰ m²/S |
| | ferri-cyanide | |

| | |
|---|---|
| ${D}_{A B} = \frac{1.17 \times {10}^{- 13} ( {ɛ}_{B} {M}_{B} ) \frac{1}{2} T}{{μ V}_{A}^{0.6}}$ | (9) |

where A represents the solute (e.g., glucose or the mediator) and B the solvent (e.g., water), ε_{B} the association factor of the solvent, M_{B} the molecular weight of the solvent, μ the viscosity of solution, V_{A} the molar volume of solute glucose, and T the absolute temperature.

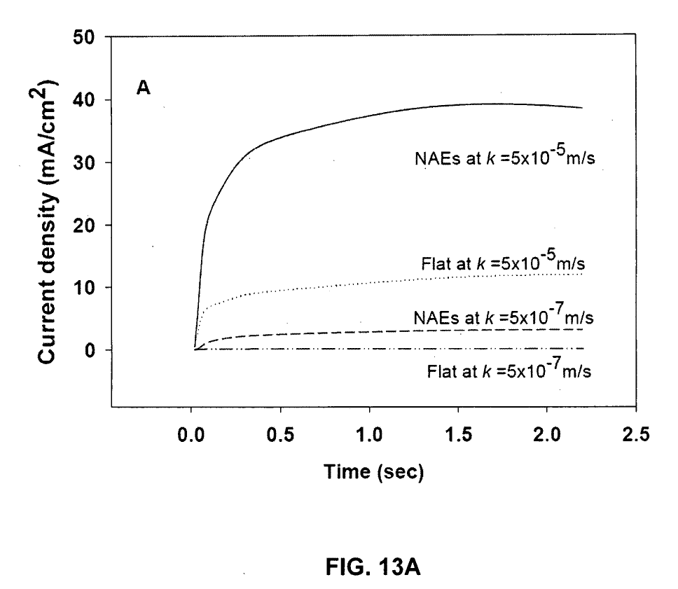

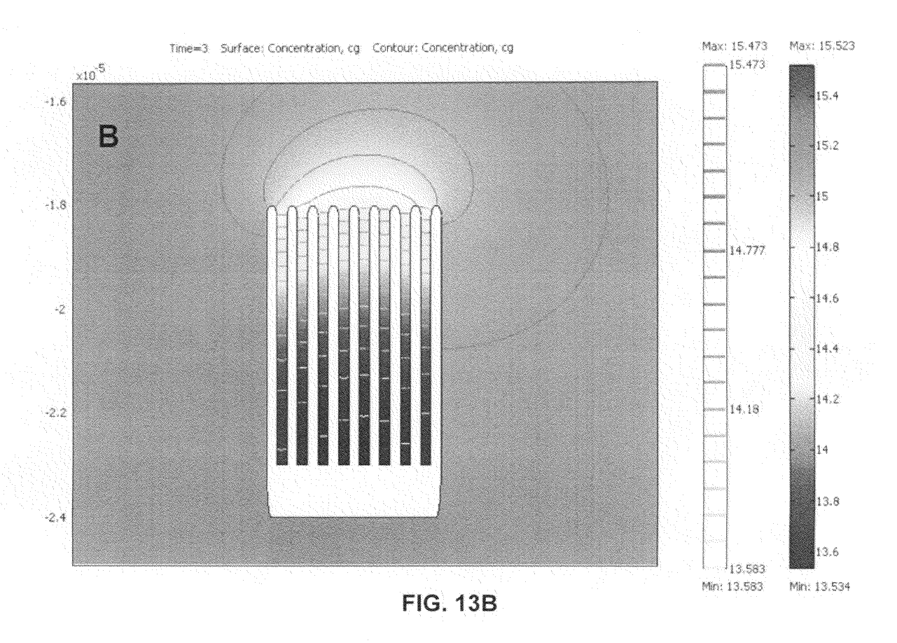

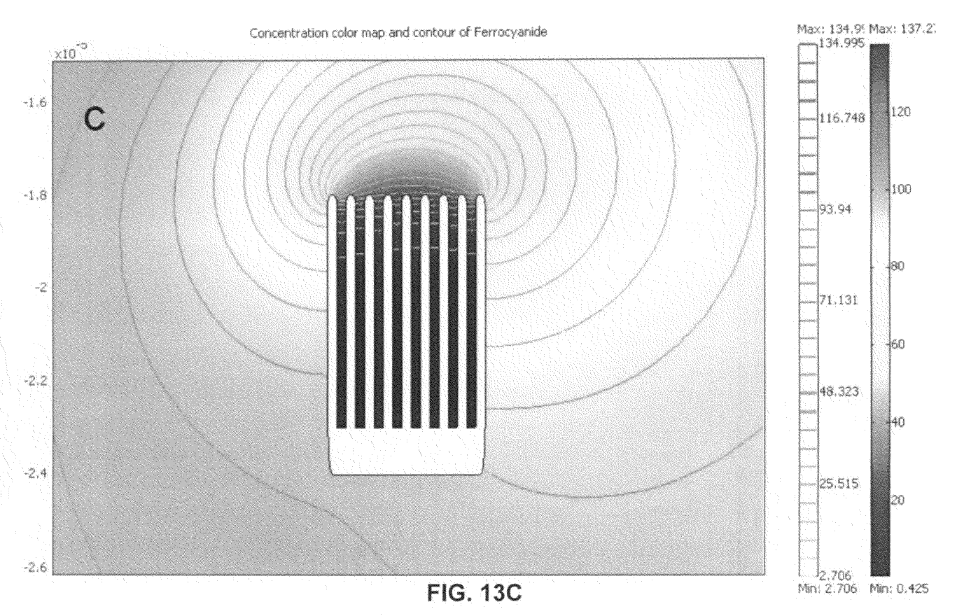

The influence of the reaction rate constant on the current response of the NAEs, can be seen from the simulation results. FIG. 13a shows the simulated amperometric current obtained for a functionalized NAEs and a flat electrode in response to glucose at two different reaction rate constants: 5×10⁻⁵ and 5×10⁻⁷ (m/s). As expected, a higher current response was found for the nanopillar electrode than for the flat electrode (see Table 3). But the nanostructure-induced increase in the current response was affected significantly by the reaction rate constant of glucose. At a rate constant of 5×10⁻⁵ m/s the increase in current due to nanopillars was only 3.26 fold, whereas at a rate constant of 5×10⁻⁷ m/s the increase was 22.26 fold. This fact suggests that at a lower reaction rate constant more glucose will be able to diffuse into the deep space between the nanopillars to get oxidized, thus leading to a higher current response. By contrast, K₄Fe(CN)₆ has a rate constant of 5×10⁻⁴, and at this rate constant the nanostructure-induced increase in current response is found to be only 1.28 fold (see Table 3). This is so because at such a high reaction rate constant, K₄Fe(CN)₆ will get oxidized quickly at the top regions of the nanopillars before it can diffuse down to the space between the nanopillars. These arguments were supported by the fact that a higher glucose concentration was found at the bottom of the spaces between nanopillars in the case with a lower reaction rate constant: a concentration of 0.497 mol/m³ and 13.583 mol/m³ was found at the bottom of the spaces between nanopillars when the rate constant is 5×10⁻⁵ m/s and 5×10⁻⁷ m/s, respectively. FIG. 13b shows a contour plot for glucose concentration at a rate constant of 5×10⁻⁷ m/s, where it is seen that a significant amount of glucose reached to the bottom of the spaces between nanopillars. In the case of K₄Fe(CN)₆ its concentration is found to be zero at the bottom of the spaces between nanopillars (see FIG. 13c).

TABLE 3
Steady-state amperometric current density obtained at different rate
constants from computer animation

| Reaction rate | Current Density (mA cm⁻²) | | |
|---|---|---|---|
| constant (m/s) | Nano | Flat | Nano/Flat |
| 5 × 10⁻⁴ for | 279.51 | 219.18 | 1.28 |
| K₄Fe(CN)₆ | | | |
| 5 × 10⁻⁵ for glucose | 39.1 | 12.0 | 3.26 |
| 5 × 10⁻⁷ for glucose | 3.25 | 0.146 | 22.26 |

### Example 7

### Simulation Study of the Electrochemical Behavior of the Proposed Microchannel Biosensors

Two-dimensional simulations were performed by solving the steady-state Navier-Stokes equation and electrokinetic equations.

Flow of solution inside the channel is defined by steady state navier-stokes equations and the mass transport of species is defined by convection and diffusion equation. The steady state Navier-stokes equation for Newtonian incompressible fluid can be written as:

∇.η(∇u+(∇u)^{T})+ρ(u.∇)u+∇p=F (10)

∇.u=0 (11)

Where ρ denotes the density of the fluid, η the dynamic viscosity, u the velocity vector, p the pressure and F is a body term. Using the above assumptions, the mass balance equation of glucose and hydrogen peroxide can be given by equation 12:

$$\begin{matrix}{D}_{i} ∇ {C}_{i} + {C}_{i} u = {N}_{i} & ( 12 ) \\ R = \frac{{V}_{max} [ S ]}{{K}_{m} + [ S ]} & ( 13 )\end{matrix}$$

Where Dᵢ denotes the diffusion coefficienct of the species i, Ni denotes the flux of the species i, Cᵢ denotes the concentration of the species i, u denotes velocity, R denotes the reaction term, Kₘ denotes the Michaelis-Menten constant, [S] the substrate concentration and Vₘₐₓ the maximum reaction rate. The reaction rate of glucose to hydrogen peroxide was assumed to obey the Michaelis-Menten kinetics which is given by equation 13.

At the walls of the channel no-slip boundary condition (velocity vector, u=0) is applied. A normal flow/pressure boundary condition is imposed at the outlet, i.e. u.t=0, p=0, where t and p denotes the tangential velocity to the boundary and pressure, respectively. At the inlet of the channel a fully developed flow is assumed to be entering which is defined by equation 5:

u=uₘₐₓ4s(1−s) (14)

Where uₘₐₓ denotes the maximum velocity in the parabolic expression and s the boundary variable that varies from 0 to 1 along the boundary.

The species such as glucose and hydrogen peroxide entering the channel has an initial concentration of 6 mM and 0 mM, respectively. At the enzyme layer, it was assumed that the flux of glucose reacting is equal to the flux of hydrogen peroxide produced. It is reported that the electrochemical oxidation of hydrogen peroxide at the electrode is mass transport controlled. Therefore, the concentration of hydrogen peroxide at the detector electrode is considered to be zero. At the outlet a convective flux boundary condition is applied, which assumes that the mass flux due to diffusion and migration across this boundary is zero.

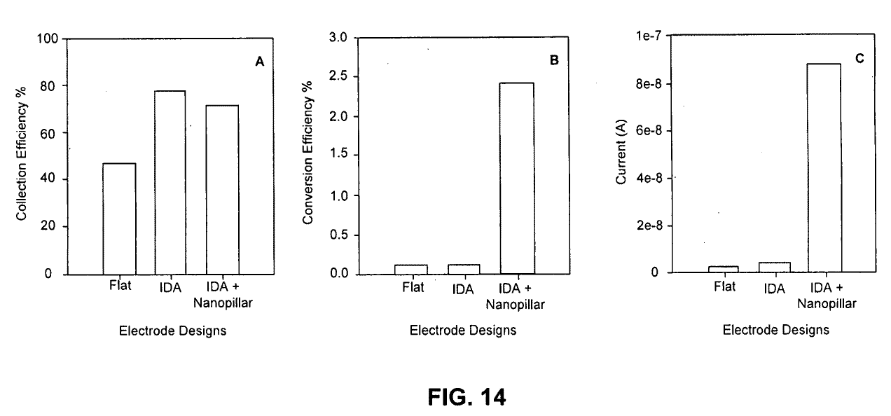

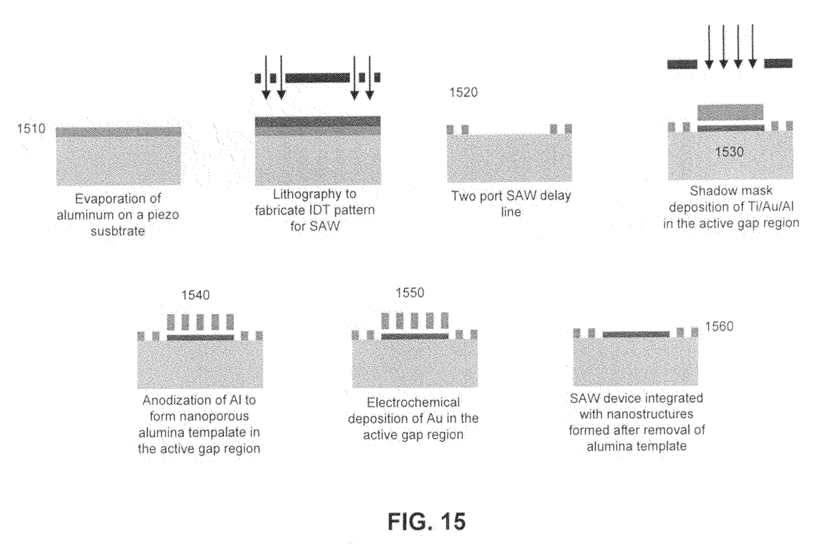

FIG. 14 demonstrates results of the simulated study conducted with a proposed microchannel biosensor. Amperometric current responses of the biosensors equipped with an interdigitated array of micro planar electrodes, either functionalized with glucose oxidase or bare, are compared to the amperometric current response of the biosensor containing flat electrode. The simulations show the proposed design will have significantly enhanced performance over conventional designs. The simulations show that the presence of nanopillars will contribute to increased efficiency and current. Adding nanopillars to the IDA will increase the current output by two orders of magnitude as compared to the conventional design.

### Example 8

### Fabrication Procedure for the SAW Biosensor Integrated With Standing Nanopillars

Interdigitated transducer pattern 1520 having at least two pairs of fingers with a width of 10 μm and spacing of 10 μm was lithographed onto a piece of a lithium niobate substrate 1510 with the dimensions of 80 μm×200 μm×40 μm coated with aluminum by evaporation. Ti, Au, and Al were shadow mask deposited in an area of 20 μm×20 μm×1 μm between the two IDTs to represent the active gap region 1530, followed by anodization of Al to form nanoporous alumina template 1540. Gold nanopillars with a diameter of 100 nm and a height of 1 μm 1550 were formed by the electrochemical deposition of gold onto the nanoporous alumina template 1540, followed by the removal of the template. The surface of the nanopillar-enhanced active area was then functionalized using the procedure described herein.

### REFERENCES

1. Berchmans S, Sathyajith R, Yegnaraman V: Layer-by-layer assembly of 1,4-diaminoanthraquinone and glucose oxidase. Materials Chemistry and Physics 2003, 77:390-396.

2. Gooding J J, Erokhin P, Hibbert D B: Parameters important in tuning the response of monolayer enzyme electrodes fabricated using self-assembled monolayers of alkanethiols. Biosensors & Bioelectronics 2000, 15:229-239.

3. Gooding J J, Praig V G, Hall E A H: Platinum-catalyzed enzyme electrodes immobilized on gold using self-assembled layers. Analytical Chemistry 1998, 70:2396-2402.

4. Losic D, Gooding J J, Shapter J G, Hibbert D B, Short K: The influence of the underlying gold substrate on glucose oxidase electrodes fabricated using self-assembled monolayers. Electroanalysis 2001, 13:1385-1393.

5. Gao M, Gordon L D: Biosensors Based on Aligned Carbon Nanotubes Coated with Inherently Conducting Polymers. Electroanalysis 2001, 15:1089-1094.

6. Uang Y M, Chow T C: Criteria for Designing a Polypyrrole Glucose Biosensor by Galvanostatic Electropolymerization. Electroanalysis 2002, 14:1564-1570.

7. Qiaocui S, Tuzhi P, Yunu Z, Yang C F: An Electrochemical Biosensor with Cholesterol Oxidase/Sol-Gel Film on a Nanoplatinum/Carbon Nanotube Electrode. Electroanalysis 2005, 17:857-861.

8. Delvaux M, Demoustier-Champagne S: Immobilisation of glucose oxidase within metallic nanotubes arrays for application to enzyme biosensors. Biosensors & Bioelectronics 2003, 18:943-951.

9. Wang J, Musameh M: Carbon Nanotube/Teflon Composite Electrochemical Sensors and Biosensors. Anal Chem 2003, 75:2075-2079.

10. Bharathi S, Nogami M: A glucose biosensor based on electrodeposited biocomposites of gold nanoparticles and glucose oxidase enzyme. Analyst 2001, 126:1919-1922.

11. Wang J, Nosang M, Minhee Y, Harold M: Glucose oxidase entrapped in polypyrrole on high-surface-area Pt electrodes: a model platform for sensitive electroenzymatic biosensors. Journal of Electroanalytical Chemistry 2005, 575:139-146.

12. Anandan V, Rao Y L, Zhang G: Nanopillar array structures for high performance electrochemical sensing. International journal of nanomedicine 2006, 1:73-79.

13. Gooding J J, Erokhin P, Losic D, Yang W, Policarpio V, Liu J, Ho F, Situmorang M, Hibbert D B, Shapter J G: Parameters important in fabricating enzyme electrodes using self-assembled monolayers of alkanethiols. Anal Sci 2001, 17(1):3-9.

14. Winkler K: The kinetics of electron transfer in Fe(CN)6 4-/3-redox system on platinum standard-size and ultramicroelectrodes. Journal of Electroanalytical Chemistry 1995, 388:151-159.

15. M. Penza, F. Antolini, M. V. Antisari, Carbon nanotubes as SAW chemical sensor materials, Sensors and Actuators B 100 (2004) 47-59.

16. M. Penza, M. A. Tagliente, P. Aversa, G. Cassano, Organic vapor detection using carbon nanotube composites microacoustic sensors, Chemical Physical Letters 409 (2005) 349-354.

The above references are herein incorporated by reference in their entirety.

What is claimed is:

1. A process for fabricating a nanostructure-enhanced 3D surface, comprising:
(a) consecutively depositing at least two layers of metallic film on a flat substrate;
(b) developing a nanoporous template by anodizing the outer metallic layer;
(c) electrodepositing nanoparticles onto said nanoporous template; and
(d) removing the template.

2. The process of claim 1, wherein said template is removed completely.

3. The process of claim 1, wherein said template is removed partially.

4. The process of claim 1, wherein said nanoparticles are nanopillars.

5. The process of claim 4, wherein said nanopillars are substantially vertical.

6. The process of claim 4, wherein a height-to-width ratio of said nanopillars is 1 to 50.

7. The process of claim 1, wherein said flat substrate is glass or silicon.

8. The process of claim 1, wherein said surface is that of an electrode.

9. The process of claim 1, wherein said metallic films are selected from the group consisting of gold, silver, aluminum, titanium, platinum, copper, palladium, and combinations thereof.

10. The process of claim 1, wherein a first metallic film is titanium.

11. The process of claim 10, wherein said titanium film has a thickness of 5-20 nm.

12. The process of claim 1, wherein a second metallic film is gold.

13. The process of claim 12, wherein said gold film has a thickness of 10-150 nm.

14. The process of claim 1, wherein a third metallic film is aluminum.

15. The process of claim 14, wherein said aluminum film has a thickness of 100 nm-1.2 μm.

16. The process of claim 1, wherein said nanoparticles are made from a metal selected from the group consisting of gold, silver, platinum, copper, palladium, and combinations thereof.

17. The process of claim 16, wherein said nanoparticles are gold.

18. The process of claim 1, wherein at least one nanopillar is further functionalized to detect a target analyte.

19. The process of claim 18, wherein said nanopillar is functionalized with a macromolecule capable of accelerating a reduction/oxidation chemical transformation utilizing a redox co-factor.

20. The process of claim 19, wherein said redox co-factor is FAD or NADH.

21. The process of claim 19, wherein said nanopillar is functionalized with glucose oxidase.

22. An integrated micro/nanoscale structure comprising:
(a) a substantially flat support base;
(b) a plurality of nanopillars connected directly to the support base, said plurality of nanopillars being substantially vertical in orientation to the support base, and said plurality of nanopillars forming a three-dimensional surface, said nanopillars comprising a height-to-width ratio of 1 to 50.

23. The structure of claim 22, wherein said surface is micropatterned.

24. A device comprising the integrated micro/nanoscale structure of claim 22.

25. The device of claim 24, wherein said device is a biosensor.

26. A microflow channel comprising an interdigitated array of microplanar electrodes, which comprises a first nanoelectrode, said first nanoelectrode comprising:
(a) a substantially flat support base;
(b) a plurality of nanopillars connected directly to the support base, said plurality of nanopillars being substantially vertical in orientation to the support base, and said plurality of nanopillars forming a three-dimensional surface, said nanopillars comprising a height-to-width ratio of 1 to 50; and
(c) a second nanoelectrode, said second nanoelectode being a nanoelectrode detector;
wherein the interdigitated array comprises a detector:electrode repeat, wherein said repeat is repeated at least twice.

27. The microflow channel of claim 26, wherein said repeat is repeated at least three times.

28. A method of detecting a target analyte in a sample, comprising:
(a) bringing a biosensor in contact with a sample;
(b) detecting generation of free electrons;
(c) determining whether said sample contains the target analyte by measuring an amperometric current, wherein the presence and magnitude of the current indicates a presence and an amount of the target analyte,
wherein said biosensor contains at least one nanopillar-enhanced electrode prepared by the process of claim 6.

29. The method of claim 28, wherein said sample is a biological fluid.

30. The method of claim 29, wherein said analyte is an endogenous or an exogenous molecule.

31. The method of claim 30, wherein said analyte is glucose.

32. A microelectromechanical device comprising the integrated micro/nano structure of claim 22.

33. The device of claim 32, wherein said device is a three-dimensional SAW sensor.

34. The SAW sensor of claim 33 comprising a piezoelectric material, a chemically active layer, and interdigitated transducers.

35. The SAW sensor of claim 34, wherein the chemically active layer is on the propagation path of an acoustic wave.

36. The SAW sensor of claim 35, wherein the chemically active layer is a material selected from the group consisting of gold, silver, platinum, aluminum, aluminum oxide, copper, palladium, and combinations thereof.

37. The SAW sensor of claim 35, wherein the chemically active layer is a piezoceramic material.

38. A method of detecting a target analyte in a sample, comprising:
(a) bringing a biosensor in contact with a sample;
(b) detecting generation of free electrons;
(c) determining whether said sample contains the target analyte by measuring an amperometric current, wherein the presence and magnitude of the current indicates a presence and an amount of the target analyte,
wherein said biosensor is the SAW sensor of claim 33.
